(19) United States
(12) Patent Application Publication
(10) Pub. No.: US 2010/0062601 A1
(43) Pub. Date: Mar. 11, 2010

(54) METHODS FOR POLISHING ALUMINUM NITRIDE

(75) Inventor: Kevin Moeggenborg, Naperville, IL (US)

Correspondence Address: STEVEN WESEMAN;ASSOCIATE GENERAL COUNSEL, I.P., CABOT MICROELECTRONICS CORPORATION, 870 NORTH COMMONS DRIVE, AURORA, IL, 60504, US

(73) Assignee: Cabot Microelectronics Corporation, Aurora, IL (US)

(21) Appl. No.: 12/312,477

(22) PCT Filed: Nov. 13, 2007
(86) PCT No.: PCT/US2007/023738

§ 371 Date: May 12, 2009

Related U.S. Application Data
(60) Provisional application No. 60/859,172, filed on Nov. 15, 2006.

(51) Int. Cl. H01L 21/306

(52) U.S. Cl. 438/692; 257/E21.23

(57) ABSTRACT

The present invention provides a method for polishing an aluminum nitride substrate. The method comprises abrading a surface of the aluminum nitride substrate with a basic, aqueous polishing composition, which comprises an abrasive (e.g., colloidal silica), an oxidizing agent (e.g., hydrogen peroxide), and an aqueous carrier. The methods of the invention provide for substantially improved polishing rates relative to conventional methods that do not utilize an oxidizing agent in the polishing slurry.

### FIELD OF THE INVENTION

This invention relates to polishing compositions and methods. More particularly, this invention relates to methods for polishing aluminum nitride-containing substrates and compositions therefore.

### BACKGROUND OF THE INVENTION

Aluminum nitride (AlN) is used as a substrate for preparing commercial semiconductor materials and devices. In particular, aluminum nitride is useful as a substrate for epitaxial growth of various crystalline materials (e.g., aluminum nitride, aluminum gallium nitride, gallium nitride, indium nitride, and the like) using techniques such as “organometallic vapor phase epitaxy” (OMVPE). Epitaxially grown materials prepared on AlN substrates can be used in the manufacture of wide-bandgap and high-temperature semiconductors for a variety of applications such as solid-state lasers, UV optical sources, UV detectors, high power microwave devices, and the like.

In order to achieve effective epitaxial growth of various nitride materials on single crystal AlN substrates, the surface of the substrate must be carefully polished, and must be substantially free from defects such as surface roughness, scratches, pits, and the like. This objective can be difficult to achieve with conventional polishing techniques.

Aluminum nitride wafers typically are cut from large, single crystals of AlN (commonly referred to as “boules”) using wire saws, diamond saws, and the like. Depending on the orientation of the cut, such wafers can have cut surfaces with significantly different physical and chemical properties. For example, opposed surfaces of wafers cut perpendicular to the crystallographic “c-axis” are polarized and have significantly different properties. One surface is predominately N-terminated (an “N-polarity c-surface”) while the opposed surface will be Al-terminated (an “Al-polarity c-surface”). These surfaces have different chemical reactivity, hardness, and other properties. For example, an Al-polarity c-surface is unreactive toward water, whereas an N-polarity c-surface reacts with water.

Cutting an AlN boule at an angle other than 90 degrees to the c-axis can produce wafers having virtually identical, non-polar surfaces, or can produce surfaces having varying degrees of polarity, depending on the angle of the cut relative to the c-axis, as is well known in the art. Non-polar AlN surfaces are reactive towards water, like N-polarity c-surfaces.

Compositions and methods for chemical-mechanical polishing (CMP) of the surface of a substrate are well known in the art. Polishing compositions (also known as polishing slurries, CMP slurries, and CMP compositions) for CMP of surfaces of semiconductor substrates (e.g., integrated circuits) typically contain an abrasive, various additive compounds, and the like in an aqueous carrier.

In general, CMP involves the concurrent chemical and mechanical abrasion of a surface of a substrate. Descriptions of chemical mechanical polishing can be found, for example, in U.S. Pat. No. 4,671,851, U.S. Pat. No. 4,910,155 and U.S. Pat. No. 4,944,836.

In conventional CMP techniques, a substrate carrier or polishing head is mounted on a carrier assembly and positioned in contact with a polishing pad in a CMP apparatus. The carrier assembly provides a controllable pressure (referred to as a “down-force”) to the substrate, urging the substrate against the polishing pad. The pad and carrier (with its attached substrate) are moved relative to one another. The relative movement of the pad and the substrate in contact therewith serves to abrade the surface of the substrate and thereby remove a portion of the material from the substrate surface. The polishing of the substrate surface typically is aided by the chemical activity of the polishing composition (e.g., by oxidizing agents, acids, bases, or other additives present in the CMP composition) and/or the mechanical activity of an abrasive suspended in the polishing composition. Typical abrasive materials include, for example, silicon dioxide, cerium oxide, aluminum oxide, zirconium oxide, and tin oxide.

U.S. Pat. No. 7,037,838 to Schowalter, et al., for example, describes a method for chemically-mechanically polishing an aluminum nitride substrate by contacting the surface of the AlN with an oxidant-free, aqueous polishing slurry comprising silica at a pH of at least about 10.5. Such polishing slurries and conditions can require lengthy periods of time to adequately polish an aluminum nitride surface, such as the Al-polarity c-surface of AlN.

Although CMP slurry compositions are known that are suitable for a variety of application, many conventional compositions tend to exhibit unacceptable polishing rates for polishing AlN. Accordingly, there is an ongoing need for methods and compositions that provide acceptable aluminum nitride polishing rates, while also providing AlN surfaces suitable for use as epitaxial growth substrates.

### SUMMARY OF THE INVENTION

The present invention provides methods for polishing an aluminum nitride surface and polishing compositions useful in such methods. The polishing methods of the invention comprise abrading a surface of an aluminum nitride substrate with a basic, aqueous polishing composition comprising an abrasive and an oxidizing agent. Preferably, the abrasive (e.g., silica) is present in the composition in an amount in the range of about 1 to about 25 percent by weight, more preferably about 15 percent by weight. The composition preferably includes about 0.1 to about 2.5 percent by weight of an oxidizing agent (e.g., hydrogen peroxide), and has a basic pH, preferably about 10.

The methods of the present invention provide polished AlN surfaces suitable for use as substrates for epitaxial growth. Such polished surfaces are relatively defect-free and are obtained at acceptable, and relatively high AlN removal rates relative to polishing with a conventional, oxidant-free, high-pH silica slurry, such as described by Schowalter et al., supra.

### DETAILED DESCRIPTION OF THE INVENTION

The polishing methods of the invention comprise abrading a surface of an aluminum nitride substrate with a basic, aqueous polishing composition comprising an abrasive and an oxidizing agent in an aqueous carrier. In some preferred embodiments, the surface being polished is an Al-polarity c-surface, although any surface of AlN may be polished in the present methods.

The methods of the invention can use any abrasive material having a hardness suitable for abrading an aluminum nitride surface. Abrasive materials are well known in the CMP art. Preferably, the abrasive comprises a silica material, such as colloidal silica, which preferably is present in the composition in an amount in the range of about 1 to about 25 percent by weight, more preferably about 15 percent by weight. A preferred colloidal silica has a mean particle size of about 80 nm.

The composition also preferably includes about 0.1 to about 2.5 percent by weight of an oxidizing agent. Oxidizing agents are well known in the CMP art, as well. A preferred oxidizing agent is hydrogen peroxide. The oxidizing agent can be added to the composition prior to initiation of polishing.

Polishing compositions used in the present methods have a basic pH, preferably about 10. The pH can be adjusted to optimize polishing rate and the like, depending on the particular surface of AlN being polished (i.e., an N-polarity surface, an Al-polarity surface, or a non-polar surface).

The methods of the present invention provide polished AlN surfaces suitable for use as substrates for epitaxial growth at acceptable, and relatively high removal rates relative to polishing with a conventional oxidant-free, high-pH silica slurry as described in Schowalter et al.

In a preferred embodiment, the method of the invention comprises abrading a surface of a silicon nitride-containing substrate with a polishing composition comprising colloidal silica and hydrogen peroxide in an aqueous carrier having a basic pH. The polishing is preferably accomplished using a CMP apparatus.

As used herein and in the appended claims, the term “colloidal silica” refers to silicon dioxide that has been prepared by condensation polymerization of Si(OH)₄. The precursor Si(OH)₄ can be obtained, for example, by hydrolysis of high purity alkoxysilanes, or by acidification of aqueous silicate solutions. Such abrasive particles can be prepared in accordance with U.S. Pat. No. 5,230,833 or can be obtained as any of various commercially available products, such as the Fuso PL-1, PL-2, and PL-3 products, and the Nalco 1050, 2327, and 2329 products, as well as other similar products available from DuPont, Bayer, Applied Research, Nissan Chemical, and Clariant.

The polishing compositions of the invention also optionally can include suitable amounts of one or more additive materials commonly used in polishing compositions, such as metal complexing agents, corrosion inhibitors, viscosity modifying agents, biocides, solvents, salts (e.g., potassium acetate), and the like.

Polishing compositions for use in the methods of the present invention can be prepared by any suitable technique, many of which are known to those skilled in the art. The polishing composition can be prepared in a batch or continuous process. Generally, the polishing composition can be prepared by combining the components thereof in any order. The term “component” as used herein includes individual ingredients (e.g., colloidal silica, acids, bases, oxidizing agents, and the like), as well as any combination of ingredients. For example, the colloidal silica can be dispersed in water and the oxidizing agent can be added just prior to initiation of polishing. The pH can be adjusted at any suitable time by addition of an acid or base, as needed.

Polishing compositions useful in the methods of the present invention also can be provided as concentrates, which are intended to be diluted with an appropriate amount of aqueous solvent (e.g., water) prior to use. In such an embodiment, the polishing composition concentrate can include the various components dispersed or dissolved in aqueous solvent in amounts such that, upon dilution of the concentrate with an appropriate amount of aqueous solvent, each component of the polishing composition will be present in the polishing composition in an amount within the appropriate range for use.

In a preferred embodiment, the method comprises (i) contacting a surface of an aluminum nitride substrate with a polishing pad and a polishing composition as described herein, and (ii) moving the polishing pad and the surface of the substrate relative to one another, while maintaining at least a portion of the polishing composition between the pad and the surface, thereby abrading at least a portion of the surface to polish the substrate.

The methods of the present invention are particularly suited for use in conjunction with a chemical-mechanical polishing apparatus. Typically, the CMP apparatus comprises a carrier to which the substrate to be polished is affixed, and a platen, in opposed relation to the carrier, which, when in use, is in motion and has a velocity that results from orbital, linear, and/or circular motion. A polishing pad is attached to the surface of the platen opposite the carrier and substrate. The platen and pad move relative to the carrier and substrate, and the substrate is urged into contact with the moving pad by a down-force exerted by the carrier. The surface of the substrate is polished by urging it into contact with the moving polishing pad with a portion of the polishing composition between the surface and the pad, so as to abrade at least a portion of the substrate and thereby polish the surface.

A substrate can be planarized or polished with any suitable polishing pad (e.g., polishing surface). Suitable polishing pads include, for example, woven and non-woven polishing pads, grooved or non-grooved pads, porous or non-porous pads, and the like. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

The following example further illustrates the invention but, of course, should not be construed as in any way limiting its scope.

### EXAMPLE 1

This example illustrates a preferred embodiment of the present invention for polishing aluminum nitride substrates.

Aluminum nitride wafers are polished on a CMP apparatus utilizing an aqueous composition having a pH of about 10 and comprising about 15 percent by weight of colloidal silica (preferably having a mean particle size of about 80 nm) and about 0.5 to about 2.5 percent by weight of hydrogen peroxide. The substrate typically is polished with a down-force in the range of about 1 to about 20 pounds per square inch (psi), generally about 5 to about 10 psi. The polishing composition (slurry) is applied at a flow rate in the range of about 0.5 to about 150 milliliters per minute (mL/min), utilizing a platen speed suitable to obtain an acceptable removal rate, e.g., in the range of about 40 to about 80 revolutions per minute (rpm).

Aluminum nitride wafers were polished according to the methods of the invention using a slurry including about 15% colloidal silica (80 nm), about 0.5 to 2.5% hydrogen peroxide, at a pH of about 10, and optionally including 0 to about 0.5% by weight of potassium acetate as an additive. For comparison, AlN wafers also were polished utilizing conventional, oxidant-free polishing slurries and conditions, e.g., using a commercial slurry such as Cabot SS 25, which includes 25 percent by weight fumed silica in water and has a pH of about 11 (including potassium hydroxide as a pH adjusting agent), or SS 25E, which is similar to SS 25, but includes ammonium hydroxide as the pH adjusting agent. The methods of the present invention afforded acceptable polished MN surfaces with fewer defects and a lower surface roughness compared to surfaces polished by the conventional methods, and achieved the acceptable surface properties at significantly reduced polishing times compared to the conventional methods. Polishing times were reduced from about 20-30 hours using conventional techniques to about 5 hours using the methods of the invention.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illustrate the invention and does not impose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A method for polishing an aluminum nitride substrate, the method comprising abrading a surface of the aluminum nitride substrate with an aqueous polishing composition having a basic pH and comprising an abrasive and an oxidizing agent.

2. The method of claim 1 wherein the abrasive comprises colloidal silica.

3. The method of claim 1 wherein the abrasive is present in the composition in an amount in the range of about 1 to about 25 percent by weight.

4. The method of claim 1 wherein the abrasive is present in the composition in an amount of about 15 percent by weight.

5. The method of claim 1 wherein the pH of the polishing composition is about 10.

6. The method of claim 1 wherein the oxidizing agent comprises hydrogen peroxide.

7. The method of claim 1 wherein the oxidizing agent is present in the polishing composition in an amount in the range of about 0.1 to about 2.5 percent by weight.

8. The method of claim 1 wherein the surface of the aluminum nitride substrate to be polished is an Al-polarity c-surface.

9. A chemical-mechanical polishing (CMP) method for polishing an aluminum nitride substrate, the method comprising the steps of:
(a) contacting a surface of the aluminum nitride substrate with a polishing pad and an aqueous CMP composition having a basic pH, the CMP composition comprising about 1 to about 25 percent by weight of colloidal silica and about 0.1 to about 2.5 percent by weight of hydrogen peroxide; and
(b) causing relative motion between the polishing pad and the substrate while maintaining a portion of the CMP composition in contact with the surface between the pad and the substrate for a time period sufficient to abrade aluminum nitride from the surface.

10. The method of claim 9 wherein the surface of the substrate comprises an Al-polarity c-surface.

11. The method of claim 9 wherein the colloidal silica is present in the composition in an amount of about 15 percent by weight.

12. The method of claim 9 wherein the pH of the polishing composition is about 10.

13. The method of claim 9 wherein the polishing composition further comprises a salt additive.

14. The method of claim 9 wherein the polishing composition further comprises potassium acetate.
